(19) United States
(12) Patent Application Publication
(10) Pub. No.: US 2012/0031336 A1
(43) Pub. Date: Feb. 9, 2012

(54) CHEMICAL VAPOR DEPOSITION DEVICE

(75) Inventor: CHIA-LING HSU, Tu-Cheng (TW)

(73) Assignee: HON HAI PRECISION INDUSTRY CO., LTD., Tu-Cheng (TW)

(21) Appl. No.: 13/114,040

(22) Filed: May 24, 2011

(30) Foreign Application Priority Data
Aug. 9, 2010 (TW) 99126471

(51) Int. Cl. C23C 16/455

(52) U.S. Cl. 118/723 R; 118/715; 118/724

(57) ABSTRACT

A chemical vapor deposition device includes a chamber, a gas input assembly, a gas output assembly, a heating device, and a driving module. The chamber includes a first side, a second side and a deposition area defined between the first side and the second side. The second side is opposite to the first side. The gas input assembly is positioned at the first side of the chamber. The gas input assembly includes a jet module. The jet module faces the deposition area to introduce reaction gases. The gas output assembly is positioned at the second side of the chamber. The gas output assembly exhausts the gases in the chamber. The heating device heats the deposition area. The driving module drives a deposition roll located in the deposition area.

### BACKGROUND

1. Technical Field

The disclosure relates to chemical vapor deposition devices, and more particularly to a chemical vapor deposition device for printing optical films.

2. Description of the Related Art

A number of microstructures are formed on a deposition roll of a chemical vapor deposition device. However, because particles can contaminate the surface of the microstructures, the thickness of films formed by chemical solution deposition is not uniform.

Therefore, it is desired to provide a new chemical vapor deposition device which can overcome the above-mentioned limitations.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is schematic view of a chemical vapor deposition device in accordance with one embodiment of the disclosure.

FIG. 2 is a cross-section taken along line II-II of the chemical vapor deposition device in FIG. 1.

### DETAILED DESCRIPTION

The disclosure is illustrated by way of example and not by way of limitation in the figures of the accompanying drawings. It should be noted that references to “an” or “one” embodiment in this disclosure are not necessarily to the same embodiment, and such references mean at least one.

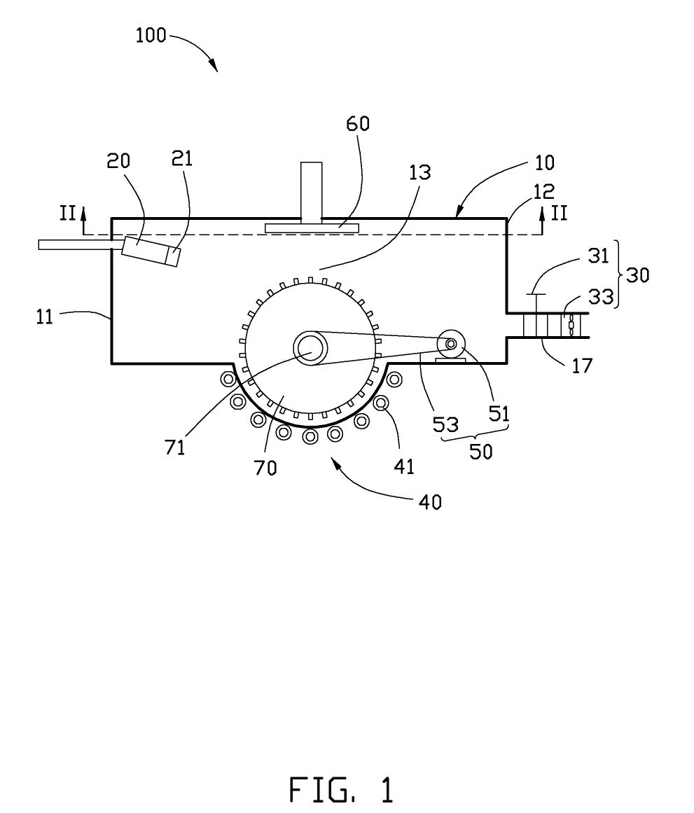

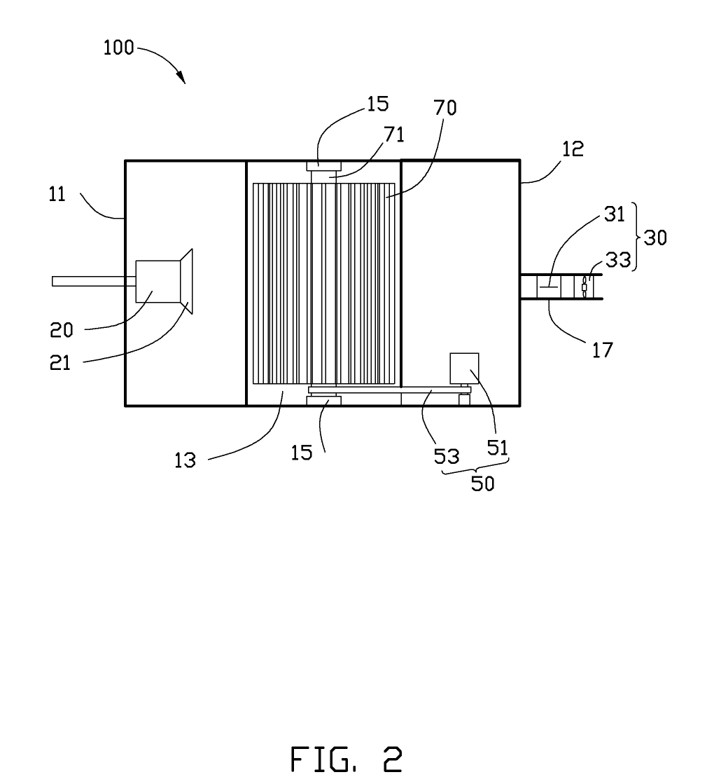

Referring to FIGS. 1-2, a chemical vapor deposition device 100 in accordance with one embodiment of the disclosure includes a chamber 10, a gas input assembly 20, a gas output assembly 30, a heating device 40, a driving module 50 and an ionization device 60.

The chamber 10 includes a first side 11, a second side 12 and a deposition area 13. The second side 12 is opposite to the first side 11. The deposition area 13 is defined between the first side 11 and the second side 12. In use, a deposition roll 70 is located in the deposition area 13. In the embodiment, a sidewall of the chamber 10 corresponding to the deposition area 13 is curved.

The gas input assembly 20 is configured for inputting reaction gases to the deposition roll 70 in the chamber 10 to form a film on a surface of the deposition roll 70. The gas output assembly 30 is configured for exhausting the gases in the chamber 10 for generating a stable airflow.

The heating device 40 is configured for heating the deposition area 13 in the chamber 10 to maintain a stable temperature around the surface of the deposition roll 70. Thus, the reaction gas around the surface of the deposition roll 70 can be heated to obtain a proper reaction temperature.

The driving module 50 is configured for driving the deposition roll 70 to rotate relative to a rotating shaft 71 of the deposition roll. Thus, uniform film can be formed on the surface of the deposition roll 70. The ionization device 60 is configured for ionizing the reaction gases in the chamber 10 to concentrate the ions of the gases around the surface of the deposition roll 70. The efficiency of forming films on the surface of the deposition roll 70 increases accordingly.

The chemical vapor deposition device 100 further includes two bearings 15. The two bearings 15 are configured for supporting the shaft 71 of the deposition roll 70. A line defined between the two bearings 15 is perpendicular to a line defined between a center of the first side 11 and a center of the second side 12. The two bearings 15 can be rolling bearings or sliding bearings.

The gas input assembly 20 is positioned on an upper portion of the first side 11. The gas input assembly 20 includes a jet module 21. The jet module 21 is configured for injecting air to the deposition area 13. The gas input assembly 20 is connected to a gas source (not shown). In the embodiment, the gas input assembly 20 is defined on the center of the upper side of the first side 11.

The reaction gases can be different gases, such as (SiH₄, N₂), (AlCl₃, NH₃) or (TiCl₄, N₂, H₂). The reaction gases can be changed to obtain films of different characters. The different reaction gases can be mixed in advance or respectively introduced to the deposition area 13.

Optimally, the jet module 21 includes a plurality of nozzles (not shown). The mixed gas can be mixed more uniformly through the nozzles. The different gases can also be respectively introduced to the surface of the deposition roll 70 through the plurality of the nozzles and then be mixed uniformly. Optimally, the directions of the nozzles can be adjusted. Therefore, the gas can be introduced to different areas of the surface of the deposition roll 70 through the nozzles from different directions.

The gas output assembly 30 is positioned on a bottom portion of the second side 12 of the chamber 10. The gas output assembly 30 is configured for exhausting reaction air from the chamber 10. Air flow from the first side 11 to the second side 12 will be generated through the gas output assembly 30. Accordingly, the airflow from the first side 11 to the second side 12 goes through the deposition area 13.

The airflow through the deposition area 13 increases the distribution area of the air and exhausts the gas that has not reacted.

The chemical vapor deposition device 100 further includes a tube 17. The tube 17 is defined in the second side 12 of the chamber 10. The gas output assembly 30 includes a gate 31 and a pump 33. The tube 17 passes through the sidewall of the second side 12. The gate 31 is defined in the tube 17 and is adjacent to the exterior of the chamber 10. The gate 31 is configured for adjusting the exhausted gas flowing through the tube 17.

The heating device 40 is defined in the bottom of the deposition area 13 and defined on the sidewall corresponding to the deposition area 13. The heating device 40 is configured for heating the deposition area 13 and providing proper reaction temperature for the reaction gases. In the embodiment, the heating device 40 includes a plurality of heating windings 41. The heating windings 41 are resistive and regularly defined below the chamber 10 corresponding to the deposition area 13. Thus, the heating device 40 can uniformly heat the deposition area 13.

The driving module 50 is connected to the deposition roll 70 in the deposition area 13. The driving module 50 is configured for driving the deposition roll 70 from the first side 11 to the second side 12. The deposition roll 70 rotates relative to the rotating shaft 71.

The driving module 50 can be defined in the chamber 10 and adjacent to the gas output assembly 30. The driving module 50 can also be defined outside of the chamber 10. The driving module 50 includes a motor 51 and a belt 53. The motor 51 is connected to the shaft 71 through belt 53. The driving module 50 can control the rotational velocity. Accordingly, the reaction gases on the surface of the deposition roll 70 can be substantially reacted.

The ionization device 60 is defined on upper side of the chamber 10. The ionization device 60 faces the deposition area 13. The ions of the gas generated by the ionization device 60 are distributed around the deposition area 13. The ionization device 60 is configured for adjusting the density of the ions around the deposition area 13. In the embodiment, the ionization device 60 is planar and parallel to the shaft 71 of the deposition roll 70. A length of the ionization device 60 exceeds that of the deposition roll 70. Thus, the ions of the reaction gas can be substantially distributed on the surface the deposition roll 70.

In the deposition process, the film thickness on different surfaces of the deposition roll 70 can be adjusted through the nozzles of different directions, rotational velocity of the deposition roll 70 and the density of the ions of reaction gas.

The deposition areas on the surface of the deposition roll 70 can be adjusted through the nozzles of different directions. Thus, a large-sized deposition area can be obtained. Thickness of film formed on the plurality of micro-structures of the deposition roll 70 can be uniform.

While the disclosure has been described by way of example and in terms of exemplary embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chemical vapor deposition device, comprising:
a chamber comprising a first side, a second side and a deposition area defined between the first side and the second side, the second side being opposite to the first side;
a gas input assembly positioned at the first side of the chamber, the gas input assembly comprising a jet module, the jet module facing the deposition area to introduce reaction gases;
a gas output assembly positioned at the second side of the chamber, the gas output assembly configured for exhausting the gases in the chamber to generate an airflow from the first side through the deposition area to the second side;
a heating device configured for heating the deposition area; and
a driving module configured for driving a deposition roll located in the deposition area.

2. The chemical vapor deposition device of claim 1, wherein a sidewall of the chamber corresponding to the deposition area is curved.

3. The chemical vapor deposition device of claim 1, wherein the heating device comprises a plurality of heating windings regularly positioned below the deposition area.

4. The chemical vapor deposition device of claim 1, further comprising an ionization device, the ionization device being positioned above the deposition area and facing the deposition area.

5. The chemical vapor deposition device of claim 4, wherein the ionization device is planar.

6. The chemical vapor deposition device of claim 1, further comprising a tube positioned at the second side and passing through a sidewall of the chamber, wherein the gas output assembly comprises a gate and a pump, the pump is positioned in the tube and configured for exhausting the gases in the chamber, the gate is positioned in the tube and configured for controlling the exhausted gases flowing through the tube.

7. The chemical vapor deposition device of claim 1, further comprising two bearings configured for supporting a rotating shaft of the deposition roll, a line connected between the two bearings being perpendicular to a line connected between a center of the first side and a center of the second side.

8. The chemical vapor deposition device of claim 1, wherein the driving module is positioned on the bottom of the chamber and adjacent to the gas output assembly.

9. The chemical vapor deposition device of claim 1, wherein the driving module comprises a motor and a belt, the motor is configured for driving the deposition roll through the belt.

10. A chemical vapor deposition device, comprising:
a chamber comprising a first side, a second side and a deposition area defined between the first side and the second side, the second side being opposite to the first side;
a gas input assembly positioned on an upper portion of the first side, the gas input assembly comprising a jet module, the jet module comprising a plurality of nozzles, a direction of each nozzle being capable of being adjusted, the jet module facing the deposition area to introduce reaction gases;
a gas output assembly positioned on a bottom portion of the second side, the gas output assembly being configured for exhausting the gases in the chamber to generate an airflow from the first side through the deposition area to the second side; a heating device configured for heating the deposition area; and
a driving module configured for driving a deposition roll located in the deposition area.

11. The chemical vapor deposition device of claim 10, wherein a sidewall of the chamber corresponding to the deposition area is curved.

12. The chemical vapor deposition device of claim 10, wherein the heating device comprises a plurality of heating windings regularly positioned below the deposition area.

13. The chemical vapor deposition device of claim 10, further comprising an ionization device positioned above the deposition area and facing the deposition area.

14. The chemical vapor deposition device of claim 13, wherein the ionization device is planar.

15. The chemical vapor deposition device of claim 10, further comprising a tube positioned at the second side and passing through a sidewall of the chamber, wherein the gas output assembly comprises a gate and a pump, the pump is positioned in the tube and configured for exhausting the gases in the chamber, the gate is positioned in the tube and configured for controlling the exhausted gases flowing through the tube.

16. The chemical vapor deposition device of claim 10, further comprising two bearings configured for supporting a rotating shaft of the deposition roll, a line connected between the two bearings being perpendicular to a line connected between a center of the first side and a center of the second side.

17. The chemical vapor deposition device of claim 10, wherein the driving module is positioned on the bottom of the chamber and adjacent to the gas output assembly.

18. The chemical vapor deposition device of claim 10, wherein the driving module comprises a motor and a belt, the motor is configured for driving the deposition roll through the belt.
